(19) United States
(12) Patent Application Publication
(10) Pub. No.: US 2016/0327602 A1
(43) Pub. Date: Nov. 10, 2016

(54) PROTECTING A REMOVABLE DEVICE FROM SHORT CIRCUITS

(71) Applicant: SanDisk Technologies Inc., Plano, TX (US)

(72) Inventors: Ramakrishnan Karungulam Subramanian, Bangalore (IN); Anand Venkitachalam, Bangalore (IN)

(73) Assignee: SANDISK TECHNOLOGIES INC., Plano, TX (US)

(21) Appl. No.: 14/706,219

(22) Filed: May 7, 2015

(51) Int. Cl. G01R 31/04; H02H 1/00; H02H 3/36

(52) U.S. Cl. CPC G01R 31/045; H02H 3/36; H02H 1/0007

(57) ABSTRACT

Circuitry may be used to detect and prevent short circuits in removable or connectable media, such as memory cards. The media may be any device or component with connections to another device, such as a host device that receives a memory card. The host device may connect with the media through connectors (which may include a plurality of pads) that facilitate a connection. If the connection between the host device and the media is improper or misaligned because the respective connectors/pads do not connect properly, then there may be a short circuit. A short circuit detector can both detect and prevent this short circuit.

### TECHNICAL FIELD

This application relates generally to memory devices. More specifically, this application relates to a circuit for reducing short circuits in a removable memory device.

### BACKGROUND

Non-volatile memory systems, such as flash memory, have been widely adopted for use in consumer products. Flash memory may be found in different forms, for example in the form of a portable/removable memory card that can be carried between host devices or as a solid state disk (SSD) embedded in a host device. An improper connection of the removable memory with a host device may result in a short circuit that can damage the card. Utilizing a poly resistor that is wide enough along with a metal interconnect that can withstand the short circuit requires more area on the card. An approach to prevent a short circuit without using additional area on the card may be beneficial as product designs become smaller.

### BRIEF DESCRIPTION OF THE DRAWINGS

FIG. 1A is a block diagram of an example non-volatile memory system.

FIG. 1B is a block diagram illustrating a storage module that includes a plurality of non-volatile memory systems.

FIG. 1C is a block diagram illustrating a hierarchical storage system.

FIG. 2A is a block diagram illustrating exemplary components of a controller of a non-volatile memory system.

FIG. 2B is a block diagram illustrating exemplary components of a non-volatile memory of a non-volatile memory storage system.

FIG. 3 is an exemplary memory card with pads.

FIG. 4 is an exemplary peripheral device connecting with a host device.

FIG. 5 is a block diagram of an input-output (10) stage of a peripheral device with a bidirectional line and a bidirectional pad.

FIG. 6 is a block diagram of a peripheral device with a bidirectional line and a bidirectional pad misconnected with a host device.

FIG. 7 is a block diagram of another embodiment of a peripheral device with a bidirectional line and a bidirectional pad that is misaligned with a host device.

FIG. 8 is a block diagram of a peripheral device with a short circuit detector or protector.

FIG. 9 is a circuit diagram of an exemplary short circuit detector or protector.

FIG. 10 is a sequence diagram of short circuit timing.

FIG. 11 is a flowchart illustrating short circuit detection.

### DESCRIPTION OF THE EMBODIMENTS

By way of introduction, the embodiments described below include circuitry and methods for reducing short circuits in removable/connectable media. The media may be any device or component with connections to another device. The media may be referred to as a media device, peripheral device, and/or memory device. In one example, a host device may connect with the media through connectors (which may include a plurality of pads) that facilitate a connection. The connection may be for the flow of data or power. If the connection between the host device and the media is improper or misaligned because the respective connectors/pads do not connect properly, then there may be a short circuit.

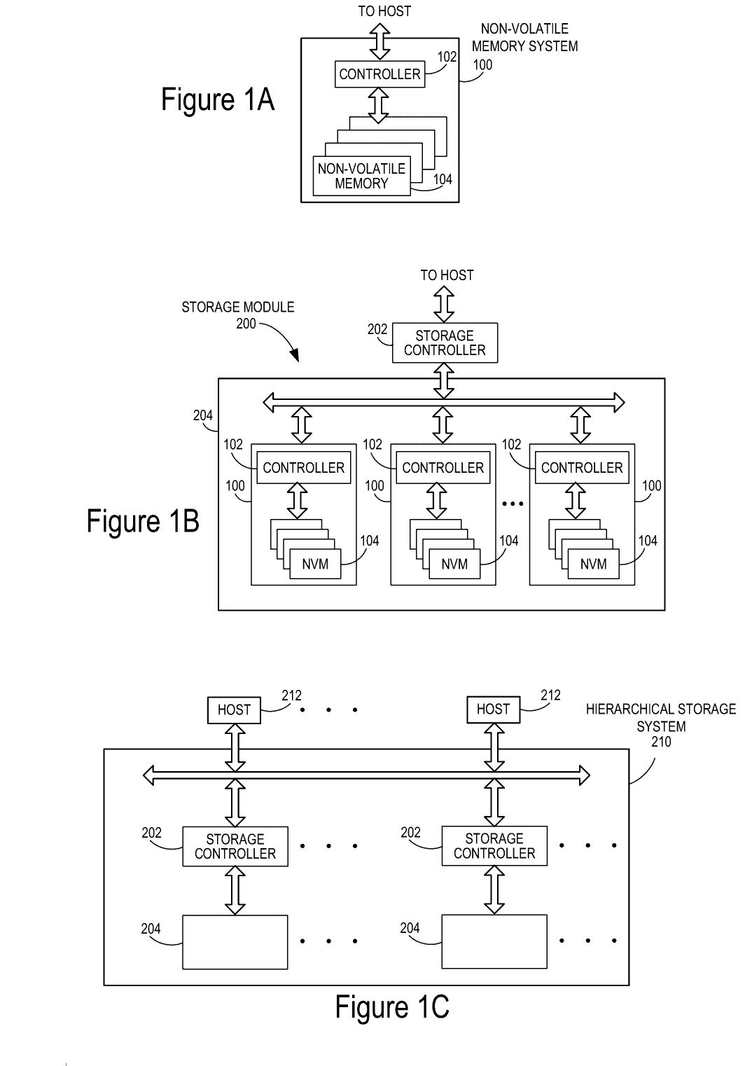

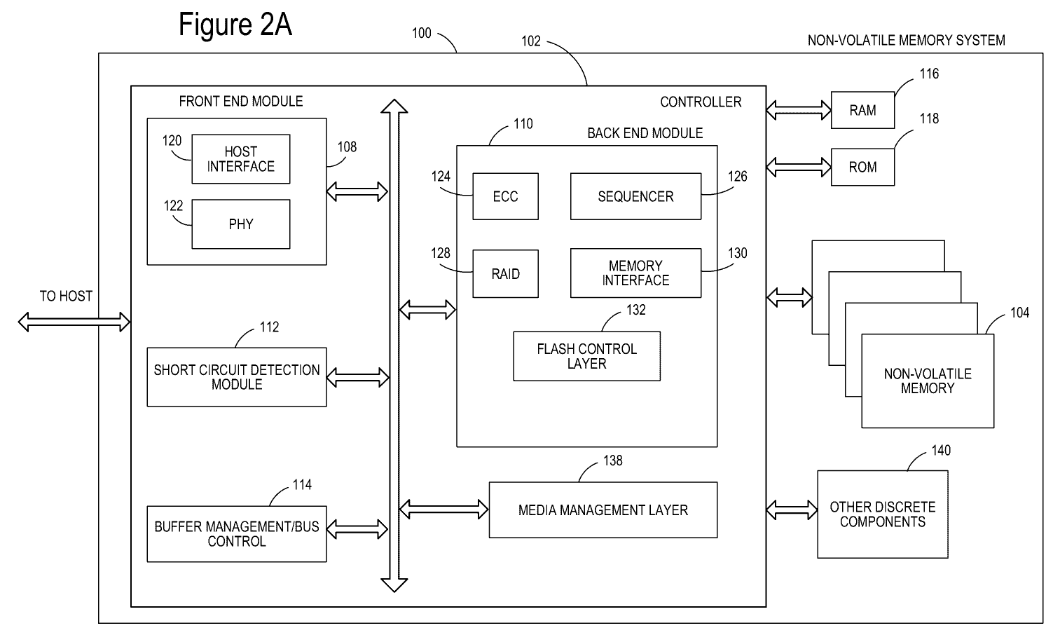

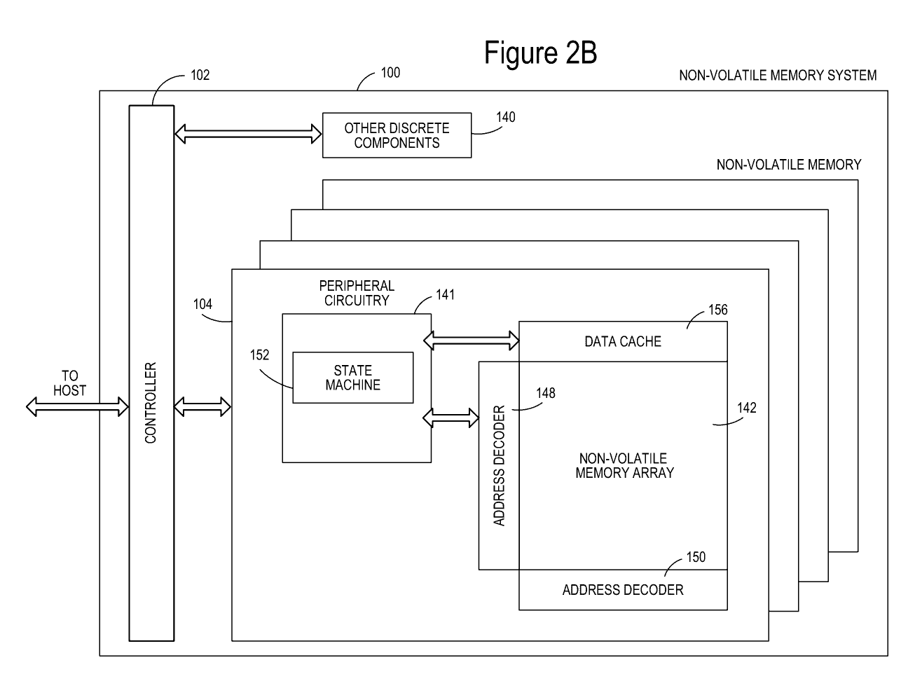

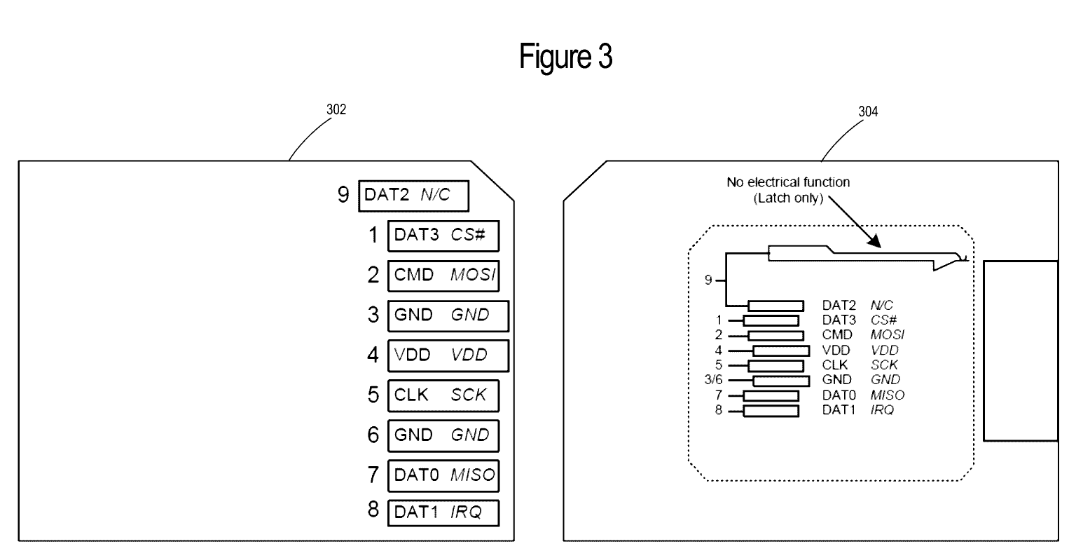

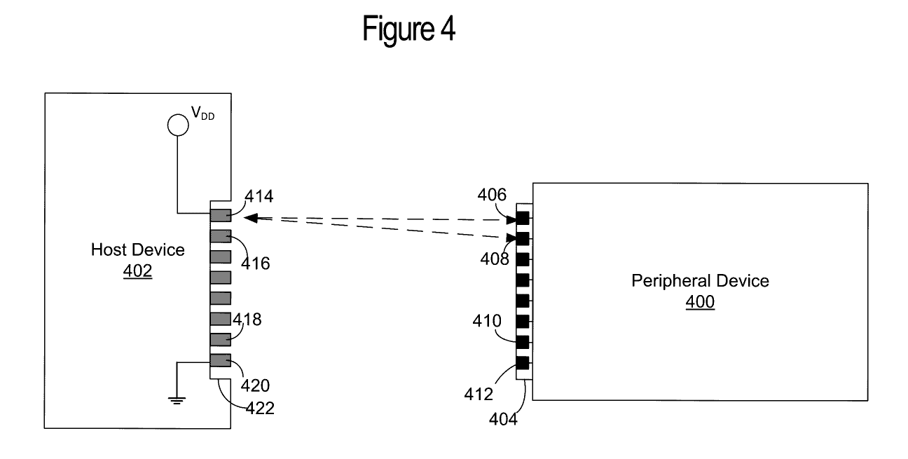

As described below, the connectable media may be removable memory, such as flash memory that includes a memory card (e.g. SD card, USB memory stick, etc.). FIGS. 1A-2B illustrate an exemplary memory system in which the non-volatile memory may be one example of a removable/connectable media with connectors for connecting to the host. The removable memory is merely one example of a connectable component that may utilize the short circuit reduction systems and methods described below. FIGS. 3-4 illustrate an exemplary device that couples with a host device. The connectors of the memory device and host device may include electrical pads that match up with one another as shown in FIGS. 3-4. In particular, the removable memory may have pads that match up with corresponding pads of a host device.

A removable memory device or memory card is merely one example of a device that is connected and can utilize the short detection and/or short protection features described below. FIGS. 1A-2B illustrate an exemplary memory and host connection. FIG. 1A is a block diagram illustrating a non-volatile memory system. The non-volatile memory system 100 includes a controller 102 and non-volatile memory that may be made up of one or more non-volatile memory die 104. As used herein, the term die refers to the set of non-volatile memory cells, and associated circuitry for managing the physical operation of those non-volatile memory cells, that are formed on a single semiconductor substrate. Controller 102 interfaces with a host system and transmits command sequences for read, program, and erase operations to non-volatile memory die 104.

Examples of host systems include, but are not limited to, personal computers (PCs), such as desktop or laptop and other portable computers, tablets, mobile devices, cellular telephones, smartphones, personal digital assistants (PDAs), gaming devices, digital still cameras, digital movie cameras, and portable media players. For portable memory card applications, a host may include a built-in receptacle for one or more types of memory cards or flash drives, or a host may require adapters into which a memory card is plugged. The memory system may include its own memory controller and drivers but there may also be some memory-only systems that are instead controlled by software executed by the host to which the memory is connected. In some memory systems containing the controller, especially those embedded within a host, the memory, controller and drivers are often formed on a single integrated circuit chip. The host may communicate with the memory card using any communication protocol such as but not limited to Secure Digital (SD) protocol, Memory Stick (MS) protocol and Universal Serial Bus (USB) protocol.

The controller 102 (which may be a flash memory controller) can take the form of processing circuitry, a microprocessor or processor, and a computer-readable medium that stores computer-readable program code (e.g., software or firmware) executable by the (micro)processor, logic gates, switches, an application specific integrated circuit (ASIC), a programmable logic controller, and an embedded microcontroller, for example. The controller 102 can be configured with hardware and/or firmware to perform the various functions described below and shown in the flow diagrams. Also, some of the components shown as being internal to the controller can also be stored external to the controller, and other components can be used. Additionally, the phrase “operatively in communication with” could mean directly in communication with or indirectly (wired or wireless) in communication with through one or more components, which may or may not be shown or described herein.

As used herein, a flash memory controller is a device that manages data stored on flash memory and communicates with a host, such as a computer or electronic device. A flash memory controller can have various functionality in addition to the specific functionality described herein. For example, the flash memory controller can format the flash memory to ensure the memory is operating properly, map out bad flash memory cells, and allocate spare cells to be substituted for future failed cells. Some part of the spare cells can be used to hold firmware to operate the flash memory controller and implement other features. In operation, when a host needs to read data from or write data to the flash memory, it will communicate with the flash memory controller. If the host provides a logical address to which data is to be read/written, the flash memory controller can convert the logical address received from the host to a physical address in the flash memory. (Alternatively, the host can provide the physical address). The flash memory controller can also perform various memory management functions, such as, but not limited to, wear leveling (distributing writes to avoid wearing out specific blocks of memory that would otherwise be repeatedly written to) and garbage collection (after a block is full, moving only the valid pages of data to a new block, so the full block can be erased and reused).

Non-volatile memory die 104 may include any suitable non-volatile storage medium, including NAND flash memory cells and/or NOR flash memory cells. The memory cells can take the form of solid-state (e.g., flash) memory cells and can be one-time programmable, few-time programmable, or many-time programmable. The memory cells can also be single-level cells (SLC), multiple-level cells (MLC), triple-level cells (TLC), or use other memory cell level technologies, now known or later developed. Also, the memory cells can be fabricated in a two-dimensional or three-dimensional fashion. The interface between controller 102 and non-volatile memory die 104 may be any suitable flash interface, such as Toggle Mode 200, 400, or 800. In one embodiment, memory system 100 may be a card based system, such as a secure digital (SD) or a micro secure digital (micro-SD) card. In an alternate embodiment, memory system 100 may be part of an embedded memory system. For example, the flash memory may be embedded within the host, such as in the form of a solid state disk (SSD) drive installed in a personal computer.

Although in the example illustrated in FIG. 1A, non-volatile memory system 100 includes a single channel between controller 102 and non-volatile memory die 104, the subject matter described herein is not limited to having a single memory channel. For example, in some NAND memory system architectures, such as in FIGS. 1B and 1C, 2, 4, 8 or more NAND channels may exist between the controller and the NAND memory device, depending on controller capabilities. In any of the embodiments described herein, more than a single channel may exist between the controller and the memory die, even if a single channel is shown in the drawings.

FIG. 1B illustrates a storage module 200 that includes plural non-volatile memory systems 100. As such, storage module 200 may include a storage controller 202 that interfaces with a host and with storage system 204, which includes a plurality of non-volatile memory systems 100. The interface between storage controller 202 and non-volatile memory systems 100 may be a bus interface, such as a serial advanced technology attachment (SATA) or peripheral component interface express (PCIe) interface. Storage module 200, in one embodiment, may be a solid state drive (SSD), such as found in portable computing devices, such as laptop computers, and tablet computers.

FIG. 1C is a block diagram illustrating a hierarchical storage system. A hierarchical storage system 210 includes a plurality of storage controllers 202, each of which control a respective storage system 204. Host systems 212 may access memories within the hierarchical storage system via a bus interface. In one embodiment, the bus interface may be a non-volatile memory express (NVMe) or a fiber channel over Ethernet (FCoE) interface. In one embodiment, the system illustrated in FIG. 1C may be a rack mountable mass storage system that is accessible by multiple host computers, such as would be found in a data center or other location where mass storage is needed.

FIG. 2A is a block diagram illustrating exemplary components of controller 102 in more detail. Controller 102 includes a front end module 108 that interfaces with a host, a back end module 110 that interfaces with the one or more non-volatile memory die 104, and various other modules that perform functions which will now be described in detail. A module may take the form of a packaged functional hardware unit designed for use with other components, a portion of a program code (e.g., software or firmware) executable by a (micro)processor or processing circuitry that usually performs a particular function of related functions, or a self-contained hardware or software component that interfaces with a larger system, for example. For example, each module may include an application specific integrated circuit (ASIC), a Field Programmable Gate Array (FPGA), a circuit, a digital logic circuit, an analog circuit, a combination of discrete circuits, gates, or any other type of hardware or combination thereof. Alternatively or in addition, each module may include memory hardware, such as a portion of the memory 104, for example, that comprises instructions executable with a processor to implement one or more of the features of the module. When any one of the modules includes the portion of the memory that comprises instructions executable with the processor, the module may or may not include the processor. In some examples, each module may just be the portion of the memory 104 or other physical memory that comprises instructions executable with the processor to implement the features of the corresponding module.

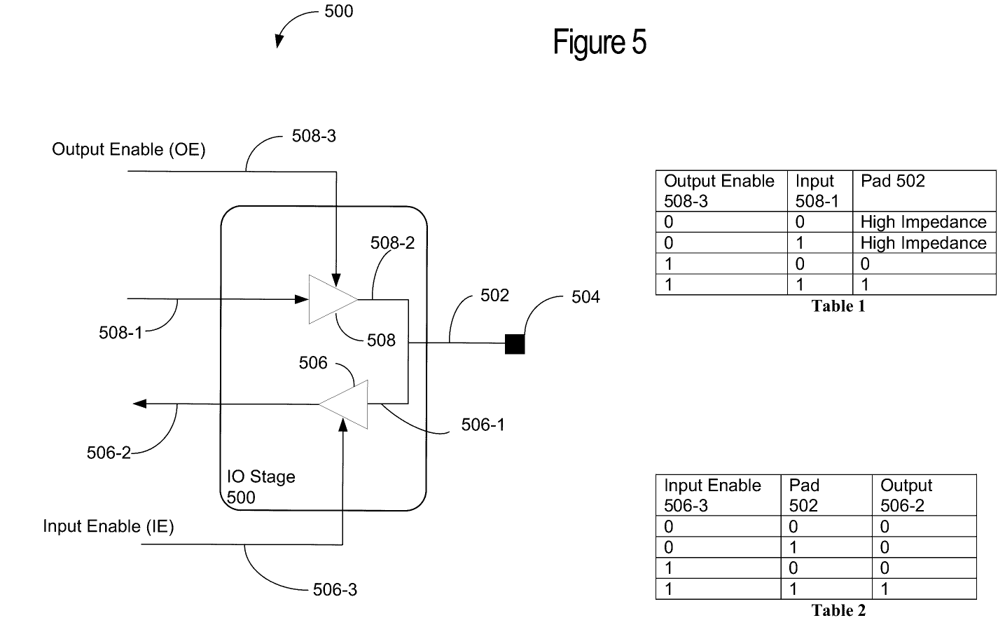

Modules of the controller 102 may include a short circuit detection module 112 present on the die of the controller 102. The short circuit detection module may also be referred to as a short circuit protection module. As explained in more detail below in conjunction with FIGS. 5-11, the short circuit detection module 112 may identify potential short circuit condition (e.g. misalignment of a connection) and prevent a short circuit (i.e. protect from a short circuit). The electrical pads (connector) of the memory system 100 may be part of the front end module 108 and the short circuit detection module 112 can monitor the connection and has circuitry (e.g. FIGS. 5-9) configured to handle a potential short circuit.

Referring again to modules of the controller 102, a buffer manager/bus controller 114 manages buffers in random access memory (RAM) 116 and controls the internal bus arbitration of controller 102. A read only memory (ROM) 118 stores system boot code. Although illustrated in FIG. 2A as located separately from the controller 102, in other embodiments one or both of the RAM 116 and ROM 118 may be located within the controller. In yet other embodiments, portions of RAM and ROM may be located both within the controller 102 and outside the controller. Further, in some implementations, the controller 102, RAM 116, and ROM 118 may be located on separate semiconductor die.

Front end module 108 includes a host interface 120 and a physical layer interface (PHY) 122 that provide the electrical interface with the host or next level storage controller. The choice of the type of host interface 120 can depend on the type of memory being used. Examples of host interfaces 120 include, but are not limited to, SATA, SATA Express, SAS, Fibre Channel, USB, PCIe, and NVMe. The host interface 120 typically facilitates transfer for data, control signals, and timing signals. FIGS. 3-4 illustrate one embodiment of an interface that includes a connector with electrical pads for establishing a connection with the host.

Back end module 110 includes an error correction controller (ECC) engine 124 that encodes the data bytes received from the host, and decodes and error corrects the data bytes read from the non-volatile memory. A command sequencer 126 generates command sequences, such as program and erase command sequences, to be transmitted to non-volatile memory die 104. A RAID (Redundant Array of Independent Drives) module 128 manages generation of RAID parity and recovery of failed data. The RAID parity may be used as an additional level of integrity protection for the data being written into the non-volatile memory system 100. In some cases, the RAID module 128 may be a part of the ECC engine 124. A memory interface 130 provides the command sequences to non-volatile memory die 104 and receives status information from non-volatile memory die 104. In one embodiment, memory interface 130 may be a double data rate (DDR) interface, such as a Toggle Mode 200, 400, or 800 interface. A flash control layer 132 controls the overall operation of back end module 110.

Additional components of system 100 illustrated in FIG. 2A include media management layer 138, which performs wear leveling of memory cells of non-volatile memory die 104. System 100 also includes other discrete components 140, such as external electrical interfaces, external RAM, resistors, capacitors, or other components that may interface with controller 102. In alternative embodiments, one or more of the physical layer interface 122, RAID module 128, media management layer 138 and buffer management/bus controller 114 are optional components that are not necessary in the controller 102.

The FTL or MML 138 may be integrated as part of the flash management that may handle flash errors and interfacing with the host. In particular, MML may be a module in flash management and may be responsible for the internals of NAND management. In particular, the MML 138 may include an algorithm in the memory device firmware which translates writes from the host into writes to the flash memory 104. The MML 138 may be needed because: 1) the flash memory may have limited endurance; 2) the flash memory 104 may only be written in multiples of pages; and/or 3) the flash memory 104 may not be written unless it is erased as a block. The MML 138 understands these potential limitations of the flash memory 104 which may not be visible to the host. Accordingly, the MML 138 attempts to translate the writes from host into writes into the flash memory 104. As described below, erratic bits may be identified and recorded using the MML 138. This recording of erratic bits can be used for evaluating the health of blocks.

FIG. 2B is a block diagram illustrating exemplary components of non-volatile memory die 104 in more detail. Non-volatile memory die 104 includes peripheral circuitry 141 and non-volatile memory array 142. Non-volatile memory array 142 includes the non-volatile memory cells used to store data. The non-volatile memory cells may be any suitable non-volatile memory cells, including NAND flash memory cells and/or NOR flash memory cells in a two dimensional and/or three dimensional configuration. Peripheral circuitry 141 includes a state machine 152 that provides status information to controller 102. Non-volatile memory die 104 further includes a data cache 156 that caches data.

FIG. 3 is an exemplary memory card with pads. FIG. 3 illustrates views of exemplary secure disk (SD) cards 302, 304 that each include a connector portion with a plurality of pads. An electrical pad or simply a pad may correspond to a layer of conductive material such as copper that may be connected to internal componentry of the device. The layer may be referred to as the contact surface of the pad. The pads are labeled 1-9 and have different functions. For example, pads 3, 6 are ground pads, pad 4 is a power pad, pad 2 is a command signal pad, pads 1, 7-9 are data signal pads, and pad 5 is a clock signal pad. The connector pads of the SD card are matched up with connector pads for the host device. If the card is misaligned and the corresponding pads do not touch, then the device fails to operate. If the card is misaligned such that different pads touch, then a short circuit may be caused. For example, if the power pad touches a non-power pad from the host device, then a short circuit may be caused. FIGS. 5-11 illustrate and describe short circuit protection mechanisms that can be used to handle a misalignment of pads. FIG. 4 illustrates an alternative embodiment of a device connecting with a host device using pads.

FIG. 4 is an exemplary peripheral device 400 connecting with a host device 402. The peripheral device 400 may include apparatuses and implement methods described herein to detect the status of an electrical connection between electrical pads of connector 404 of the peripheral device 400 with electrical pads of receptive connector 422 of the host device 402. In an exemplary embodiment, the host device 404 may be adapted with a receptive slot dimensioned to correspond to the dimensions of the peripheral device 400. The connector 422 of the host device 400 may be disposed at the end of the receptive slot away from the opening of the slot. The peripheral device 400 may be slid into the receptive slot to cause an electrical connection to be established between the pads of connector 422 and connector 404. The SD card shown in FIG. 3 is one example, and an embedded multimedia card (eMMC) and compact flash are other exemplary peripheral devices that may be slid into a slot of host device 402 and implement methods described herein. In one embodiment, the receptive slot may be dimensioned to only accept the connector 404 of the peripheral device 400. Another example of such a peripheral device is a universal serial bus (USB) memory stick. Digital cameras, laptops, smartphones, tablets, printers, and other computing devices are exemplary host devices that may be adapted with receptive slots suitable for connecting with the aforementioned types of peripheral devices.

An electrical connection between host device 402 and peripheral device 400 may be realized by inserting or sliding the connector 404 of peripheral device 400 into the corresponding receptive connector 422 of host device 402, thereby causing the contact surface of the pads of connector 404 to slide-ably make contact with the contact surface of the pads of connector 422. An aligned connection is realized when each of the pads of connector 404 makes contact with a corresponding intended pad of connector 422 to facilitate the transfer of electrical signals between the host device 402 and the peripheral device 400 to allow for the intended operation of the resulting system consisting of the host device 402 and the peripheral device 400. For example, an aligned connection may be when pads 406, 408, 410 and 412 of the (peripheral) connector 404 make a respective exclusive connection with pads 414, 416, 418 and 420 of the (host) connector 422. In contrast, a misaligned connection occurs when a pad of one connector makes an unintended electrical contact with an unintended pad of the other connector or with more than one pad of the other connector. A misaligned connection may occur when a user slides peripheral device 400 at an incorrect angle into the corresponding receptive connector 422 of the host device 402.

In one embodiment, the host device 404 powers the peripheral device 400. Power may be transferred from the host device 404 to the peripheral device 400 via one or more electrical pads when the electrical pads of connector 404 of the peripheral device 400 make contact with the electrical pads of receptive connector 422. One or more of the electrical pads of connector 422 may be connected to power supply componentry of the host device 402. For example, electrical pad 414 may be connected to a power source of the host device 402 and electrical pad 420 may be connected to ground. Ground is generally at a logic low level or 0 volts (V). Electrical pad 414 may be referred to as a power terminal. The host device 404 may power a suitable voltage level (e.g. 3.3 V or 5 V) at the power terminal. The electrical pad 406 of the peripheral device 400 may be configured to receive power that is used to power the peripheral device 400 and electrical pad 412 may be configured to be connected to ground. In this configuration, an aligned connection requires electrical pad 406 to make electrical contact with electrical pad 414 and for electrical pad 412 to make contact with electrical pad 420. The other electrical pads may be connected to internal circuitry adapted to allow for the communication of commands and data between the host device 402 and the peripheral device 404. These electrical pads may be referred to as data pads and the electrical lines connecting the data pads to internal circuitry may be referred to as data lines. Still other electrical pads may be connected to control circuitry that controls the exchange of information via the data lines. These pads may be referred to as control pads and the electrical lines connecting the control pads to the control circuitry may be referred to as control lines.

Based on the direction of flow of electrical signals corresponding to the control signals, commands, and data, the data lines and control lines may be bidirectional or unidirectional. A unidirectional line may communicate electrical signals from the host device 402 to the peripheral device 400 or vice versa and the electrical pad connected with the line may be referred to as a unidirectional pad. From the perspective of the peripheral device, if electrical signals are received by the peripheral device 400 via a unidirectional line, the line is an input line. Likewise, if electrical signals are transmitted by the peripheral device 400 via a unidirectional line, the line is an output line. A bidirectional line is connected to circuitry that is adapted to both receive and transmit electrical signals at different times. An electrical pad connected to a bidirectional pad may be referred to as a bidirectional pad.

FIG. 5 is a block diagram of an input-output (10) stage 500 of a peripheral device with a bidirectional line 502 and a bidirectional pad 504. The peripheral device may be the device 400 in FIG. 4 or other removable or connectable device. The bidirectional pad 504 may be adapted to make slide-able contact with a bidirectional pad of a connector of a host device when a connector on which the bidirectional pad 504 is inserted into a receptive connector of a host device. The IO stage 500 includes two tristate buffers: a tristate input buffer 506 and a tristate output buffer 508. The tristate buffers 506, 508 may each include an input, an output, and an enable line. When the enable line is active, the logic state at the input of the tristate buffer is reflected at the output. When the enable line is inactive, the output of the tristate buffer presents high impedance causing the tristate buffer and the circuitry connected to the input of the tristate buffer to be effectively disconnected from the output. The state of the enable line may be controlled by control circuitry resident in the controller of the peripheral device.

The tristate input buffer 506 includes an input buffer input line 506-1, an input buffer output line 506-2, and an input enable (IE) line 506-3. The input buffer output line 506-2 may be connected to circuitry in the peripheral device. Tristate output buffer 508 may include an output buffer input line 508-1, an output buffer output line 508-2, and an output enable (OE) line 508-3. The output buffer input line 508-1 may be connected to circuitry in the peripheral device. The output buffer output line 508-2 and the input buffer output line 506-2 may be connected to the bidirectional line 502 which may be connected with bidirectional pad 504 in one embodiment.

Control circuitry connected to OE 508-3 and IE 506-3 controls whether bidirectional line 502 is an input or an output. For example, to configure the bidirectional line 502 as an input line, control circuitry may activate line IE 506-3 and deactivate OE 508-3. Because OE 508-3 is inactive, the output buffer output line 508-2 is driven to a high impedance state and the output buffer 508 is disconnected from the bi-directional line 502. At the same time, because IE 506-3 is active, the input buffer output line 506-2 reflects the logic state of the input buffer input line 506-1. Thus any electrical signal generated by circuitry connected to an electrical pad of the host device that is in electrical contact with pad 502 is reflected at the input buffer input line 506-1.

To configure the bidirectional line 502 as an output line, control circuitry may deactivate line IE 506-3 and activate OE 508-3. Because IE 506-3 is inactive, the input buffer output line 506-2 is driven to a high impedance state and circuitry connected with the input buffer output line 506-2 is disconnected from the bi-directional line 502. At the same time, because OE 508-3 is active, the output buffer output line 508-2 reflects the logic state of the output buffer input line 508-1. Thus any electrical signal generated by circuitry connected to the output buffer input line 508-1 may be reflected at pad 502.

FIG. 5 illustrates truth tables for the tristate output buffer 508 and tristate input buffer 506. Table 1 illustrates a truth table for the tristate output buffer 508 that shows that when OE 508-3 is enabled, the output 508-2 (value at pad 502) matches the input 508-1. Table 2 illustrates a truth table for the tristate input buffer 506 that shows when IE 506-3 is enabled, the output 506-2 matches the input 506-1 (value at pad 502).

In an alternative embodiment, a similar arrangement of buffers may be utilized for a unidirectional line connected with a unidirectional pad. In this embodiment, the tristate buffers may be replaced with logic buffers. A logic buffer may not have an enable line and therefore may not have a high impedance state of a tristate buffer. Accordingly, the logic state of the output of a logic buffer is equal to the logic state of the input provided to the logic buffer. For example, if the input is set to logic high, the logic state of the output is logic high. This may occur when the tristate output buffer 508 and the tristate input buffer 506 are replaced with an output logic buffer and an input logic buffer.

The output 508-3 of output buffer 508 may be adapted with an over-current protection circuit. When the bidirectional line 502 is configured as an output line, the over-current protection circuit limits the amount of current that may flow in and out of the output buffer 508. For example, when the logic level at the output buffer output line 508-3 is low or binary 0, the over-current protection circuit limits the amount of current that may be sunk into the output buffer. When the logic level at the output buffer output line 508-3 is high or logic 1, the over-current protection circuit limits the amount of current that may be sourced by the output buffer 508.

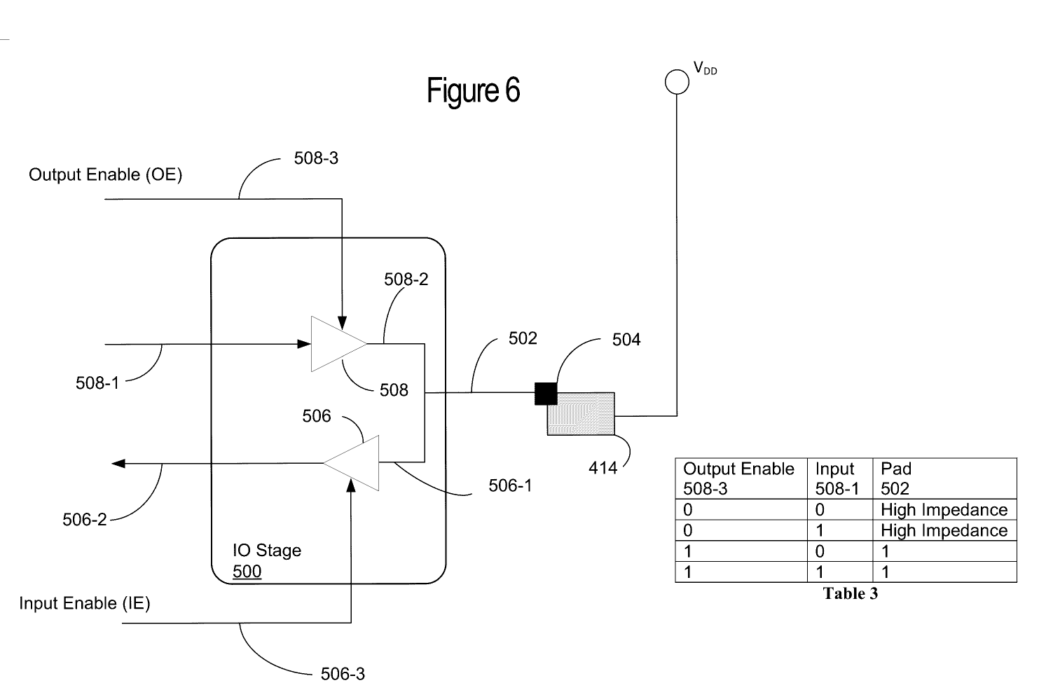

In case of a misaligned connection, the bidirectional pad 504 of the peripheral device 400 may contact a power terminal (e.g. electrical pad 414 of the host device 404). In this scenario, when bidirectional line 502 is configured as an output line and when a misaligned connection occurs, a low resistance current path is created between the power terminal and the output of the output buffer 508. This low resistance current path may be referred to as a short circuit. If the input 508-1 of the output buffer 508 is driven to a logic low state, a current corresponding to the over-current limit may be caused to flow into the output 508-2 of output buffer 508. This current level may cause heating of the pad and a process called electro migration may cause erosion of the electrical pad. This scenario is illustrated in FIG. 6.

FIG. 6 is a block diagram of an input-output (10) stage of a peripheral device with a bidirectional line and a bidirectional pad misconnected with a host device. The bidirectional pad 504 may correspond to pad 408. A misaligned connection causes bidirectional pad 504 to make electrical contact with power terminal electrical pad 414 of connector 422 of host device 402. When the output buffer 508 is enabled and the input 508-1 of output buffer 508 is set to a logic low level by circuitry of the peripheral device 402, and the output 508-2 should reflect the logic state of the input and be at logic low level. However, because of the misaligned connection, the output 508-2 is shorted to the power terminal which is at a voltage level corresponding to logic high (e.g. 3.3V or 5 V). The output impedance of the output buffer 508 will cause the output to be “pulled up” to a logic high level even though the input of output buffer is at a logic low level. This is shown in the third row of Table 3 of FIG. 6.

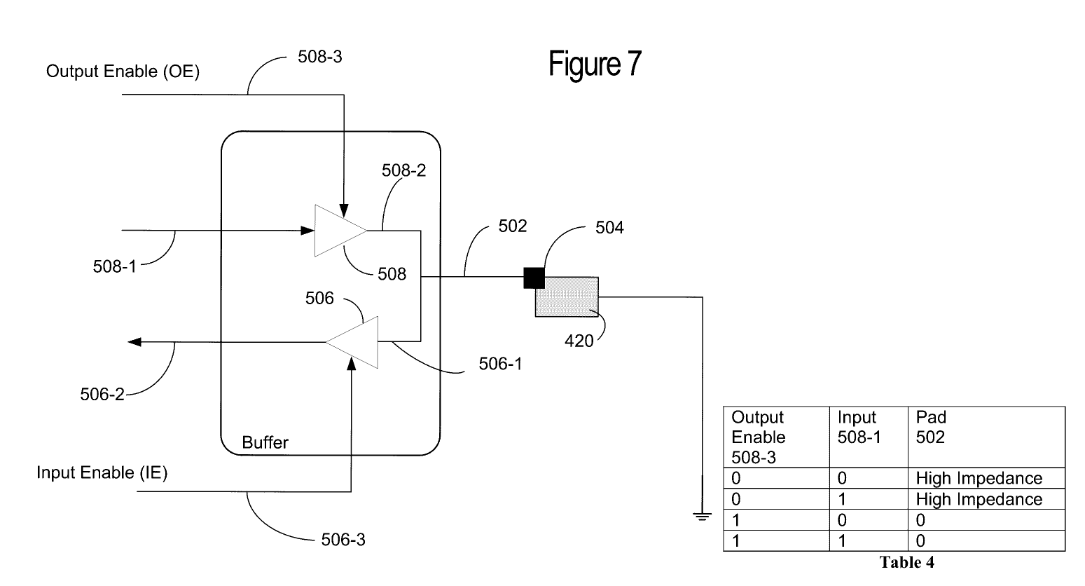

FIG. 7 is a block diagram of another embodiment of a peripheral device with a bidirectional line and a bidirectional pad that is misaligned with a host device. In the misaligned connection shown in FIG. 7, the ground pad 420 of connector 422 of host device 402 is shorted with bidirectional pad 504. In one embodiment, the bidirectional pad 504 may correspond to the electrical pad 410 and is therefore adjacent to the ground pad 420 of the connector 420. The ground pad 420 is typically at 0 V or logic low. When the output buffer 508 is enabled and the input 508-1 of the output buffer 508 is set to a logic high level, the output of the output buffer 508 will be “pulled down” to a logic low level corresponding to the voltage available at the ground pad 420. Entry of row 4 of Table 4 of FIG. 7 illustrates the logic levels in this embodiment. In one embodiment, control circuitry connected with the IO stage 500 may sense the misaligned connection of the bidirectional pad 504 to the power terminal of the host device connector 422 and take protective action to disconnect the output buffer 508 from the bidirectional pad by deactivating OE 508-3.

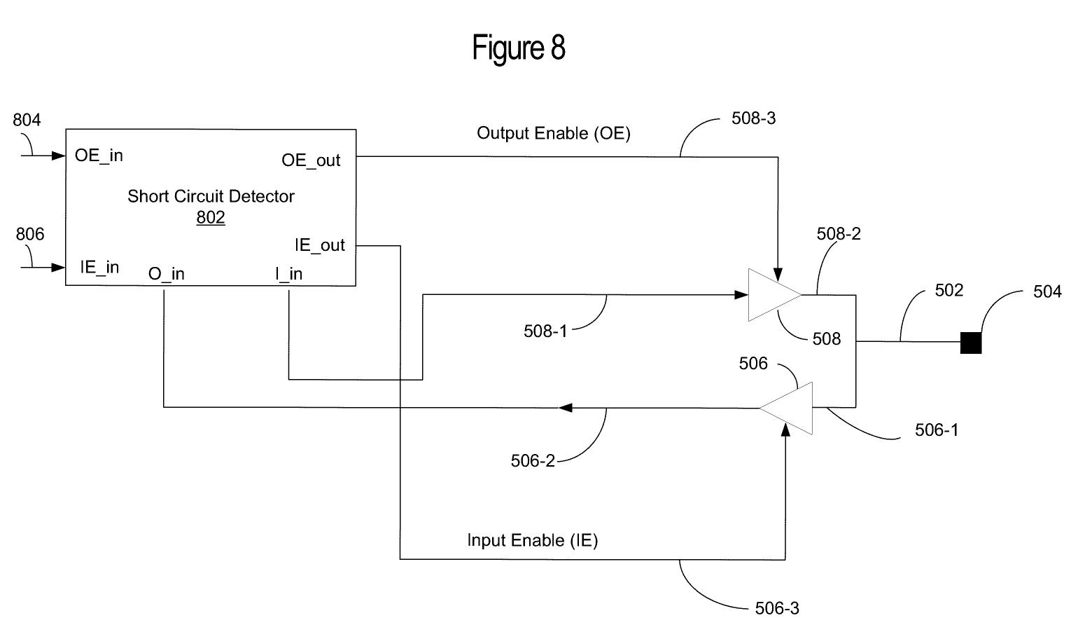

FIG. 8 is a block diagram of a peripheral device with a short circuit detector 802. As discussed, the short circuit detection may also be used for short circuit protection. The short circuit detector 802 may include circuitry for detecting and preventing a short circuit. The short circuit detector 802 may be part of or the same as the short circuit detection module 112 illustrated in FIG. 2A. The short circuit detector 802 may be used to detect a short circuit of an electrical pad of a bidirectional data line of a peripheral device with a power pad or ground pad of a connector of a host device. In this exemplary embodiment, OE_out line of short circuit detector 802 is connected with OE line 508-3 of the output buffer 508 and IE_out line of the short circuit detector 802 is connected with the IE line 506-3 of the input buffer 506. O_in line of the short circuit detector 802 is connected with the output 506-2 of the input buffer 506 and I_in line of the short circuit detector is connected with the input 508-1 of the output buffer 508.

The operation of short circuit detector 802 may be controlled by signals provided at inputs OE_in 804, IE_in 806 and I_in of the short circuit detector 802. As previously described, the electrical pad 504 may be short circuited to the power pad (FIG. 6) or the ground pad (FIG. 7). In an exemplary embodiment, IE_in may be connected with IE_out in the short circuit detector 802. To detect a short circuit to the power pad, the short circuit detector 802 may enable the input buffer 506 and the output buffer 508 by means of a respective enable signals produced at IE_out and OE_out. The short circuit detector 802 may set line I_in for the input 508-1 of output buffer 508 to a logic 0. Because both buffers are enabled, the logic level at the output 506-2 of the input buffer 506 must be equal to the logic level at the input 506-1 of the input buffer 506 which in turn must be equal to the logic level at the input 508-1 of the output buffer 508. The short circuit detector 802 may read the logic level at the output 506-2 of the input buffer 506 and compare the read logic level with the logic level set at the input 508-1 of the output buffer 508. If the logic levels are equal, the short circuit detector 802 may conclude that there is no short circuit to the power pad. However, as explained with respect to FIG. 6, in the case of a short circuit to the power pad, the input 506-1 of input buffer 506 may be “pulled up” to a logic high irrespective of the logic level at the input 508-1 of the output buffer 508. Therefore, the output 506-2 of the input buffer 506 will be logic high or 1. The logic level at the input 508-1 of the output buffer 508 which is set to 0 will not match read logic level at the output 506-2 of the input buffer 506. The short circuit detector 802 may conclude that the pad 504 is short circuited to a power pad or terminal of the connector of a host device.

To detect a short circuit to a ground pad, the short circuit detector 802 may enable the input buffer 506 and the output buffer 508 by means of a respective enable signal produced at IE_out and OE_out. In an exemplary embodiment, the short circuit detector 802 may set line I_in the input 508-1 of the output buffer 508 to a logic 1. Because both buffers are enabled, the logic level at the output 506-2 of the input buffer 506 must be equal to the logic level at the input 506-1 of the input buffer 506 which in turn must be equal to the logic level at the input 508-1 of the output buffer 508. The short circuit detector 802 may read the logic level at the output 506-2 of the input buffer 506 and compare the read logic level with the logic level set at the input 508-1 of the output buffer 508. If the logic levels are equal, the short circuit detector 802 may conclude that there is no short circuit to the power pad. However, as explained with respect to FIG. 7, in the case of a short circuit to the ground pad, the input 506-1 of the input buffer 506 will be “pulled low” to a logic low or 0 irrespective of the logic level at the input 508-1 of the output buffer 508. Therefore, the output 506-2 of input buffer 506 will be logic low or 0. Because of this, the logic level at the input 508-1 of the output buffer 508 which is set to 1 will not match read logic level at the output 506-2 of the input buffer 506. The short circuit detector 802 may conclude that the pad 504 is short circuited to a ground pad or terminal of the connector of a host device. In each case the short circuit detector may disable the output and input buffers.

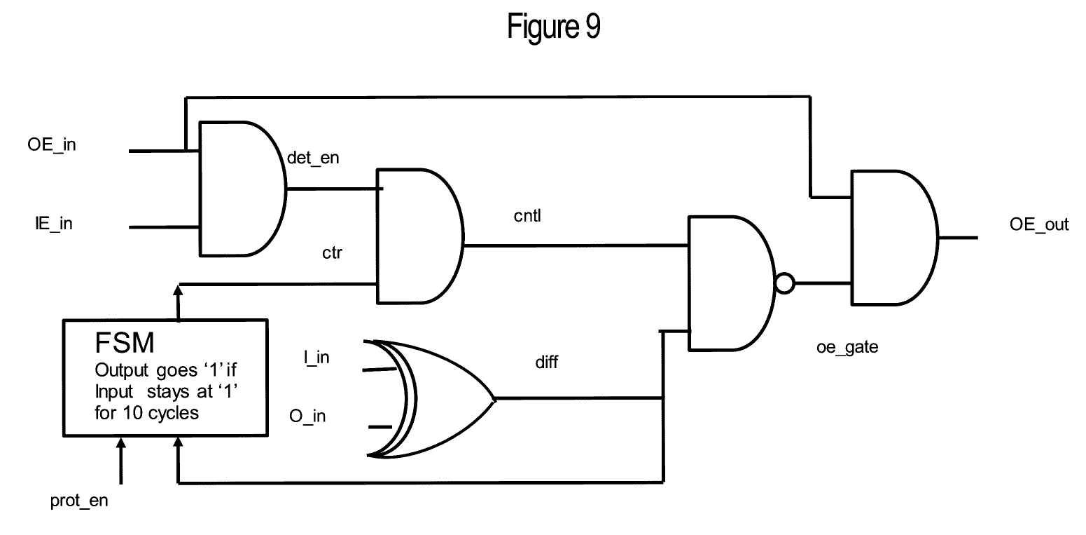

FIG. 9 is a circuit diagram of an exemplary short circuit detector 802. The short circuit detector in FIG. 9 may be the exemplary short circuit detector 802 shown in FIG. 8. The operation and results of the circuit in FIG. 9 is described with respect to FIG. 8. OE_in and IE_in are activated upon power up. If the PAD is not shorted to VDD/VSS, then the output O_in should be the same as the input I_in. If the output O_in and the input I_in are different, this indicates a short and the driver will be tri-stated or disabled by cutting the DC short circuit current.

The prot_en is input to the finite state machine (FSM). When prot_en is 1, the protection circuit will be enabled. If prot_en is 0, then the protection circuit remains disabled. The system may keep prot_en at 1 during power-up and may be kept at 0 at other times. The signal det_en is the output of the first AND gate. The short circuit detector may be enabled when OE_in and IE_in are 1 (i.e. when both output buffer and input buffer are enabled) as shown in Table 5 below:

TABLE 5
Truth Table for OE_in and IE_in with output det_en from FIG. 9

| OE_in | IE_in | det_en |
|---|---|---|
| 0 | 0 | 0 |
| 0 | 1 | 0 |
| 1 | 0 | 0 |
| 1 | 1 | 1 |

A potential short circuit may be detected when I_in and O_in are different, in which case, the diff signal goes to 1. This detection of a potential short circuit by the diff signal is shown in Table 6 below:

TABLE 6
Truth Table for diff output in FIG. 9

| I_in | O_in | diff |
|---|---|---|
| 0 | 0 | 0 |
| 0 | 1 | 1 |
| 1 | 0 | 1 |
| 1 | 1 | 0 |

The FSM may be a counter that counts the number of clock cycles at which the diff signal is at 1. The count may also count when prot_en signal is enabled. The output ctr signal of this counter may be at a default value of 0 except when it has counted 10 clock cycles, the ctr output goes to 1. The oe_gate gates OE and when oe_gate is 0 it drives OE_out to 0 instead of propagating OE_in to OE_out. This means the output buffer is tristated. Only when diff, det_en and ctr are 1 then oe_gate goes to 0. This is shown in Table 7 below:

TABLE 7
Truth Table for oe_gate output in FIG. 9

| det_en | ctr | diff | oe_gate |
|---|---|---|---|
| 0 | 0 | 0 | 1 |
| 0 | 0 | 1 | 1 |
| 0 | 1 | 0 | 1 |
| 0 | 1 | 1 | 1 |
| 1 | 0 | 0 | 1 |
| 1 | 0 | 1 | 1 |
| 1 | 1 | 0 | 1 |
| 1 | 1 | 1 | 0 |

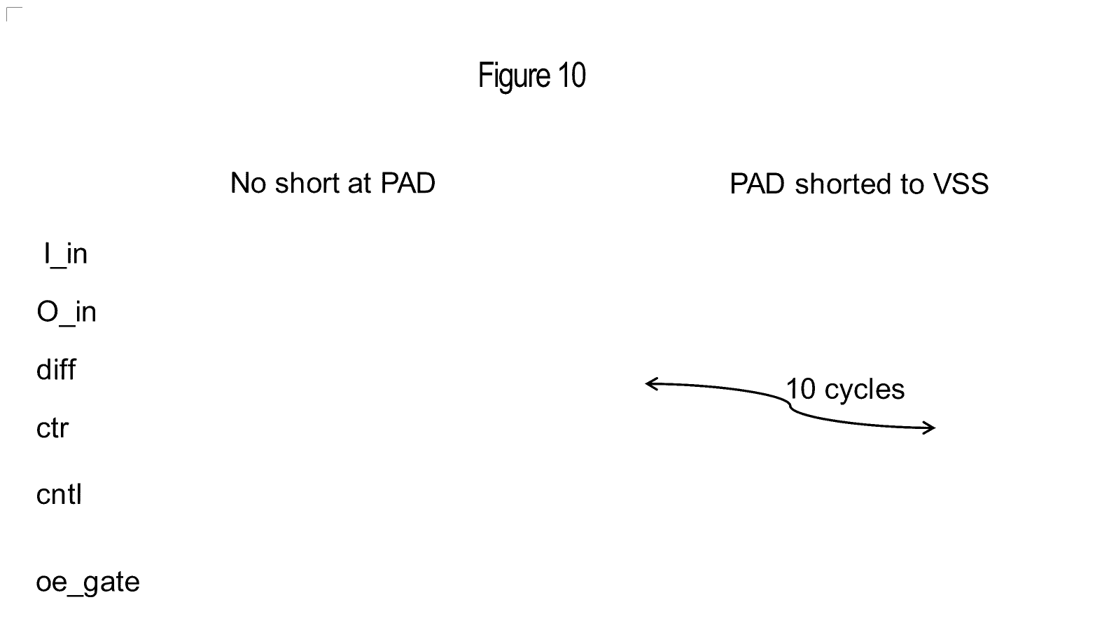

FIG. 10 is a sequence diagram of short circuit timing. The left side illustrates sequences in which there is no short at the pad, while the right side illustrates the pad being shorted to VSS. When the pad is shorted to VSS, O_in output does not trigger. After a set number of cycles (e.g. 10), if the difference (diff) is still set, then it is clear that the input I_in and output O_in are different, which signifies a potential short circuit. In the left diagram, a change to the input I_in is eventually matched by O_in (within a threshold of cycles such as 10) and the diff signal returns to low indicating no difference in the input and output. When a short is detected (after the threshold number of cycles has passed with a difference detected), the ctr signal is activated. Likewise, the control cntl signal is also activated which can deactivate the output oe_gate signal. By detecting the short circuit, the value of OE_out is changed.

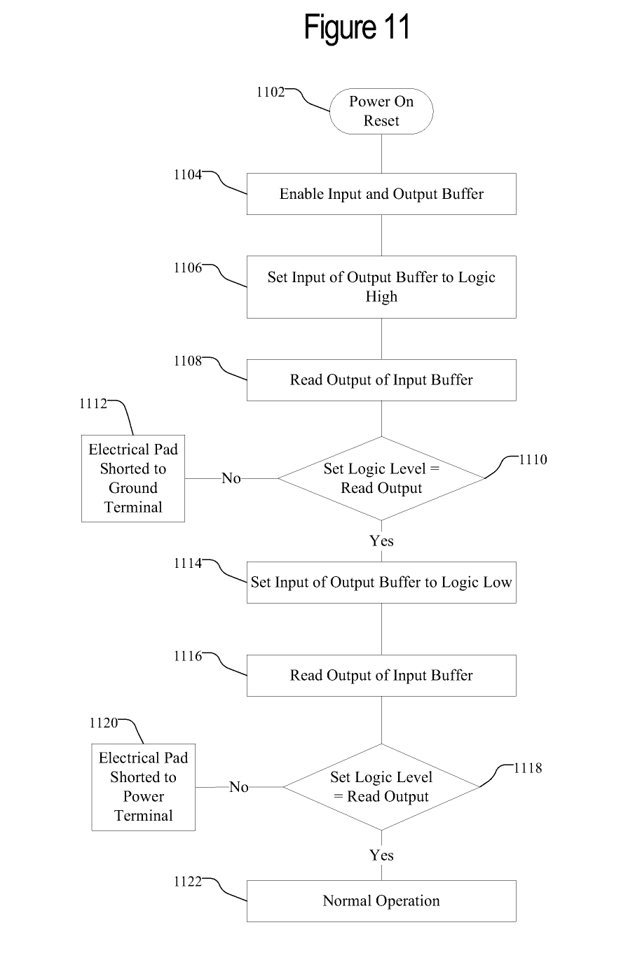

FIG. 11 is a flowchart illustrating short circuit detection. In block 1102, the device is powered on or reset. The input buffer 506 and the output buffer 508 are enabled at power up in block 1104. The input of the output buffer (output buffer input line 508-1) is set to high in block 1106. The output of the input buffer (input buffer output line 506-2) is read in block 1108. The logic level is compared to the output that is read as in block 1110. If the logic level is not equal to the read output, then the electrical pad is shorted to the ground terminal as in block 1112. If the logic level is equal to the read output, then the electrical pad is not shorted to the power terminal and the input of the output buffer (output buffer input line 508-1) is set to logic low in block 1114. The output of the input buffer (input buffer output line 506-2) is read in block 1116. The logic level is compared to the output that is read as in block 1118. If the logic level is not equal to the read output, then the electrical pad is shorted to the power terminal as in block 1120. If the logic level is equal to the read output, then the electrical pad is not shorted to the ground and device is functioning in normal operation (with no short circuit conditions) as in block 1122.

In the present application, semiconductor memory devices such as those described in the present application may include volatile memory devices, such as dynamic random access memory (“DRAM”) or static random access memory (“SRAM”) devices, non-volatile memory devices, such as resistive random access memory (“ReRAM”), electrically erasable programmable read only memory (“EEPROM”), flash memory (which can also be considered a subset of EEPROM), ferroelectric random access memory (“FRAM”), and magneto-resistive random access memory (“MRAM”), and other semiconductor elements capable of storing information. Each type of memory device may have different configurations. For example, flash memory devices may be configured in a NAND or a NOR configuration.

The memory devices can be formed from passive and/or active elements, in any combinations. By way of non-limiting example, passive semiconductor memory elements include ReRAM device elements, which in some embodiments include a resistivity switching storage element, such as an anti-fuse, phase change material, etc., and optionally a steering element, such as a diode, etc. Further by way of non-limiting example, active semiconductor memory elements include EEPROM and flash memory device elements, which in some embodiments include elements containing a charge storage region, such as a floating gate, conductive nanoparticles, or a charge storage dielectric material.

Multiple memory elements may be configured so that they are connected in series or so that each element is individually accessible. By way of non-limiting example, flash memory devices in a NAND configuration (NAND memory) typically contain memory elements connected in series. A NAND memory array may be configured so that the array is composed of multiple strings of memory in which a string is composed of multiple memory elements sharing a single bit line and accessed as a group. Alternatively, memory elements may be configured so that each element is individually accessible, e.g., a NOR memory array. NAND and NOR memory configurations are exemplary, and memory elements may be otherwise configured.

The semiconductor memory elements located within and/or over a substrate may be arranged in two or three dimensions, such as a two dimensional memory structure or a three dimensional memory structure. In a two dimensional memory structure, the semiconductor memory elements are arranged in a single plane or a single memory device level. Typically, in a two dimensional memory structure, memory elements are arranged in a plane (e.g., in an x-z direction plane) which extends substantially parallel to a major surface of a substrate that supports the memory elements. The substrate may be a wafer over or in which the layer of the memory elements are formed or it may be a carrier substrate which is attached to the memory elements after they are formed. As a non-limiting example, the substrate may include a semiconductor such as silicon.

The memory elements may be arranged in the single memory device level in an ordered array, such as in a plurality of rows and/or columns. However, the memory elements may be arrayed in non-regular or non-orthogonal configurations. The memory elements may each have two or more electrodes or contact lines, such as bit lines and word lines.

A three dimensional memory array is arranged so that memory elements occupy multiple planes or multiple memory device levels, thereby forming a structure in three dimensions (i.e., in the x, y and z directions, where the y direction is substantially perpendicular and the x and z directions are substantially parallel to the major surface of the substrate). As a non-limiting example, a three dimensional memory structure may be vertically arranged as a stack of multiple two dimensional memory device levels. As another non-limiting example, a three dimensional memory array may be arranged as multiple vertical columns (e.g., columns extending substantially perpendicular to the major surface of the substrate, i.e., in the y direction) with each column having multiple memory elements in each column. The columns may be arranged in a two dimensional configuration, e.g., in an x-z plane, resulting in a three dimensional arrangement of memory elements with elements on multiple vertically stacked memory planes. Other configurations of memory elements in three dimensions can also constitute a three dimensional memory array.

By way of non-limiting example, in a three dimensional NAND memory array, the memory elements may be coupled together to form a NAND string within a single horizontal (e.g., x-z) memory device levels. Alternatively, the memory elements may be coupled together to form a vertical NAND string that traverses across multiple horizontal memory device levels. Other three dimensional configurations can be envisioned wherein some NAND strings contain memory elements in a single memory level while other strings contain memory elements which span through multiple memory levels. Three dimensional memory arrays may also be designed in a NOR configuration and in a ReRAM configuration.

Typically, in a monolithic three dimensional memory array, one or more memory device levels are formed above a single substrate. Optionally, the monolithic three dimensional memory array may also have one or more memory layers at least partially within the single substrate. As a non-limiting example, the substrate may include a semiconductor such as silicon. In a monolithic three dimensional array, the layers constituting each memory device level of the array are typically formed on the layers of the underlying memory device levels of the array. However, layers of adjacent memory device levels of a monolithic three dimensional memory array may be shared or have intervening layers between memory device levels.

Then again, two dimensional arrays may be formed separately and then packaged together to form a non-monolithic memory device having multiple layers of memory. For example, non-monolithic stacked memories can be constructed by forming memory levels on separate substrates and then stacking the memory levels atop each other. The substrates may be thinned or removed from the memory device levels before stacking, but as the memory device levels are initially formed over separate substrates, the resulting memory arrays are not monolithic three dimensional memory arrays. Further, multiple two dimensional memory arrays or three dimensional memory arrays (monolithic or non-monolithic) may be formed on separate chips and then packaged together to form a stacked-chip memory device.

Associated circuitry is typically required for operation of the memory elements and for communication with the memory elements. As non-limiting examples, memory devices may have circuitry used for controlling and driving memory elements to accomplish functions such as programming and reading. This associated circuitry may be on the same substrate as the memory elements and/or on a separate substrate. For example, a controller for memory read-write operations may be located on a separate controller chip and/or on the same substrate as the memory elements.

One of skill in the art will recognize that this invention is not limited to the two dimensional and three dimensional exemplary structures described but cover all relevant memory structures within the spirit and scope of the invention as described herein and as understood by one of skill in the art.

A “computer-readable medium,” “machine readable medium,” “propagated-signal” medium, and/or “signal-bearing medium” may comprise any device that includes, stores, communicates, propagates, or transports software for use by or in connection with an instruction executable system, apparatus, or device. The machine-readable medium may selectively be, but not limited to, an electronic, magnetic, optical, electromagnetic, infrared, or semiconductor system, apparatus, device, or propagation medium. A non-exhaustive list of examples of a machine-readable medium would include: an electrical connection “electronic” having one or more wires, a portable magnetic or optical disk, a volatile memory such as a Random Access Memory “RAM”, a Read-Only Memory “ROM”, an Erasable Programmable Read-Only Memory (EPROM or Flash memory), or an optical fiber. A machine-readable medium may also include a tangible medium upon which software is printed, as the software may be electronically stored as an image or in another format (e.g., through an optical scan), then compiled, and/or interpreted or otherwise processed. The processed medium may then be stored in a computer and/or machine memory. In an alternative embodiment, dedicated hardware implementations, such as application specific integrated circuits, programmable logic arrays and other hardware devices, can be constructed to implement one or more of the methods described herein. Applications that may include the apparatus and systems of various embodiments can broadly include a variety of electronic and computer systems. One or more embodiments described herein may implement functions using two or more specific interconnected hardware modules or devices with related control and data signals that can be communicated between and through the modules, or as portions of an application-specific integrated circuit. Accordingly, the present system encompasses software, firmware, and hardware implementations.

The illustrations of the embodiments described herein are intended to provide a general understanding of the structure of the various embodiments. The illustrations are not intended to serve as a complete description of all of the elements and features of apparatus and systems that utilize the structures or methods described herein. Many other embodiments may be apparent to those of skill in the art upon reviewing the disclosure. Other embodiments may be utilized and derived from the disclosure, such that structural and logical substitutions and changes may be made without departing from the scope of the disclosure. Additionally, the illustrations are merely representational and may not be drawn to scale. Certain proportions within the illustrations may be exaggerated, while other proportions may be minimized. Accordingly, the disclosure and the figures are to be regarded as illustrative rather than restrictive.

It is intended that the foregoing detailed description be understood as an illustration of selected forms that the invention can take and not as a definition of the invention. It is only the following claims, including all equivalents that are intended to define the scope of the claimed invention. Finally, it should be noted that any aspect of any of the preferred embodiments described herein can be used alone or in combination with one another.

We claim:

1. A system for short circuit reduction comprising:
a host device with host pads;
a removable media with connector pads that correspond with the host pads such that the host pads align with the connector pads when the removable media is connected with the host device, wherein the removable media comprises:
a short circuit detector coupled with one or more of the connector pads that detects a misalignment of the connector pads with the host pads by comparing signals at the connector pads.

2. The system of claim 1 wherein the short circuit detector is coupled with an input buffer and an output buffer, and the signals at the connector pads comprise input and output signals to the input buffer and output buffer.

3. The system of claim 2 wherein the misalignment is detected by comparing an output of the input buffer with an input of the output buffer.

4. The system of claim 3 wherein the host pads and the connector pads comprise electrical pads.

5. The system of claim 4 wherein the electrical pads comprise data pads, power pads, ground pads, command pads, and/or clock pads.

6. The system of claim 4 wherein the misalignment is with a power pad when the input of the output buffer is set to high.

7. The system of claim 4 wherein the misalignment is with a ground pad when the input of the output buffer is set to low.

8. The system of claim 2 wherein each of the connector pads is coupled to a separate one of the input buffer and the output buffer.

9. The system of claim 8 wherein each of the connector pads is separately coupled with a short circuit detector.

10. The system of claim 1 wherein the short circuit detector comprises a short circuit detection module in a controller of the removable media.

11. The system of claim 1 wherein the removable media comprises a flash memory device.

12. A method for determining whether a pad of a removable device is subject to a short circuit, the method comprising:
setting an input of a first logic buffer to a first logic state, wherein the first logic buffer has an output connected with the pad;
comparing the first logic state with a logic state of an output of a second logic buffer, wherein the second logic buffer has an input connected with the pad; and
determining that the pad is subject to the short circuit when the first logic state is not equal to the logic state of the output of the second logic buffer.

13. The method of claim 12 wherein the comparing the first logic state with the logic state of the output of the second logic buffer comprises performing an exclusive or (XOR) operation between the first logic state and the logic state of the output of the second logic buffer.

14. The method of claim 12 further comprising enabling the first logic buffer and the second logic buffer prior to setting the input of the first logic buffer.

15. The method of claim 14 wherein the determining the short circuit establishes that the short circuit is with a power supply, the method further comprising
disabling the first logic buffer in response to determining the pad is subject to the short circuit with the power supply.

16. The method of claim 12 wherein, when the first logic state is equal to the logic state of the output of second logic buffer, the method further comprising:
setting the input of the first logic buffer to a second logic state;
comparing the second logic state with the logic state of the output of the second logic buffer; and
determining that the pad is subject to a short circuit by connection to a ground when the second logic state is not equal to the logic state of the output of the second logic buffer.

17. The method of claim 16 further comprising:
disabling the first logic buffer in response to the determining that the pad is subject to a short circuit by connection to a ground pad.

18. The method of claim 16 wherein the first logic state comprises a high value and the second logic state comprises a low value.

19. An apparatus comprising:
an output buffer with an output buffer input and an output buffer output;
an input buffer with an input buffer input and an input buffer output, wherein the output buffer output is connected with the input buffer input; and
a controller in communication with the output buffer input and the input buffer output that is configured to set the output buffer input to a first logic level and compare the first logic level with the input buffer output, wherein the controller can selectively adjust an enabled state based on the comparison.

20. The apparatus of claim 19 wherein the apparatus comprises a removable media with one or more electrical pads for connecting with a host device, further wherein the adjustment of the enabled state can prevent a short circuit condition caused by a misalignment of the electrical pads.
